(19) United States
(12) Patent Application Publication
(10) Pub. No.: US 2020/0113070 A1
(43) Pub. Date: Apr. 9, 2020

(54) Wire Harness

(71) Applicant: Yazaki Corporation, Tokyo (JP)

(72) Inventors: Jin Watanabe, Makinohara-shi (JP); Naoyuki Yoshida, Makinohara-shi (JP); Shouya Shinogaya, Makinohara-shi (JP)

(73) Assignee: Yazaki Corporation, Tokyo (JP)

(21) Appl. No.: 16/563,351

(22) Filed: Sep. 6, 2019

(30) Foreign Application Priority Data
Oct. 3, 2018 (JP) 2018-188538

(51) Int. Cl. H05K 5/00; H01B 7/00; H01R 25/00; H05K 5/02; H01R 13/50; H01R 13/648; B60R 16/02

(52) U.S. Cl. CPC H05K 5/0047; H01B 7/0045; H01B 7/009; H01R 25/006; H01R 2201/26; H01R 13/50; H01R 13/648; H01R 25/003; B60R 16/0215; H05K 5/0247

(57) ABSTRACT

A wire harness includes a standard sub-harness including a standard circuit line, an optional sub-harness including a selection circuit line, and a protector protecting trunk lines including the standard sub-harness. The protector includes a circuit network configuring a part of the selection circuit line so as to implement selectively added function in the wire harness. The selection circuit line of the optional sub-harness branched from the trunk line is connected to the circuit network of the protector.

### CROSS REFERENCE TO RELATED APPLICATIONS

This application claims priority from Japanese Patent Application No. 2018-188538 filed on Oct. 3, 2018, the entire contents of which are incorporated herein by reference.

### BACKGROUND OF THE INVENTION

### Field of the Invention

The present invention relates to a wire harness including a wire harness which includes a plurality of sub harnesses configured respectively by predetermined circuit lines, and a protector for protecting a trunk line including at least a part of the plurality of sub harnesses.

### Description of Related Art

A wire harness mounted on a vehicle such as an automobile is generally configured as an assembly obtained by bundling, for example, a plurality of sub harnesses respectively prepared for each system. The sub harnesses to be bundled are variously prepared according to required specifications of the wire harness.

Specifically, there are a wide variety of electrical components to be mounted on the vehicle corresponding to a type of the vehicle, a grade of the vehicle, and optional equipment (a sound system, a power window system or the like) selected according to a demand of a customer (driver) of the vehicle. Therefore, circuit lines configuring power supply lines, ground lines, signal lines, and communication lines which are to be connected to the various electrical components, are variously different. In order to cope with such differences in circuit lines, a bundle of circuit lines to be mounted standardly (standard circuit lines) is provided as a standard sub-harness so as to operate a drive system in units of the drive system such as an engine and a motor. Further, in order to operate optional equipment or the like to be selectively mounted, a bundle of circuit lines (selection circuit lines) to be mounted selectively and additionally is provided as an optional sub-harness.

In recent years, application of information technology (IT) to vehicles such as automatic driving technology and external environment detection technology is rapidly advancing, and both standard electrical lines and selection electrical lines are tending to increase with the introduction of IT. That is, the number of types (kind) of sub harnesses which is required to be prepared in advance has increased significantly when a wire harness is mounted on a vehicle.

Therefore, in order to prevent the increase in the number of types of sub harnesses, it is known to construct a wire harness with a circuit substrate and a plurality of sub harnesses by connecting the plurality of sub harnesses to the circuit substrate and connecting circuit lines of the sub harnesses to each other through a circuit pattern on the circuit substrate (for example, see Patent Literature 1: JP-A-2015-230873). In this wire harness, a circuit such as a branch can be provided in the circuit substrate for both the standard sub-harness and the optional sub-harness.

### [Patent Document 1] JP-A-2015-230873

According to a related art, it is not necessary to provide branches to both a standard sub-harness and an optional sub-harness by using a circuit substrate. Therefore, a shape of the sub harness is simplified without branches and an entire system can be standardized.

Each customer has extremely detailed and more and more diverse tastes and hobbies on vehicles. The increase in selection circuit lines selectively added depending on the type and grade of a predetermined vehicle may be significant. Therefore, it is assumed that there is a demand to standardize even the optional sub-harnesses configured by selection circuit lines and to reduce the number of types thereof in the future. Even if a connector provided at a tip end of the selection circuit line of the optional sub-harness is connected to a mating connector, a plurality of selection circuit lines may be arranged in an unstable state by hanging in the air.

### SUMMARY

One or more embodiments provide a wire harness system capable of simplifying assembling of a wire harness by reducing the number of types that needs to be prepared in advance for an optional sub-harness, and stably arranging a plurality of circuit wires.

In an aspect (1), one or more embodiments provide a wire harness includes a standard sub-harness including a standard circuit line, an optional sub-harness including a selection circuit line, and a protector protecting trunk lines including the standard sub-harness. The protector includes a circuit network configuring a part of circuit lines so as to implement selectively added function in the wire harness. The selection circuit line of the optional sub-harness branched from the trunk line is connected to the circuit network of the protector.

In an aspect (2), the protector may be integrated with a connector connected to the circuit network, and the selection circuit line of the optional sub-harness branched from the trunk lines of the wire harness may be connected to the circuit network via the connector.

In an aspect (3), the protector may include a protector main body and a lid covering one open surface of the protector main body. The protector main body may accommodate the circuit network. The connector may be connected to the circuit network.

In an aspect (4), the protector main body may be integrally formed with the connector which is adjacent to an outer side surface of the protector main body. The connector may be configured such that a terminal whose one end is connected to the circuit network passes through the outer side surface of the protector main body and extends inside the connector.

In an aspect (5), the connector may include an earth terminal fastened to a bolt provided on a vehicle body.

According to the aspect (1), connection or disconnection between the selection circuit lines and switching of connection such as branching of the selection circuit lines can be easily realized by changing the circuit network of the protector. Accordingly, even in a case where various connection states of the selection circuit lines are required in the optional sub-harness, the configuration of the optional sub-harness can be simplified and standardized. Therefore, the number of types that needs to be prepared in advance for the optional sub-harnesses can be reduced, and assembling of the wire harness can be simplified. As a result, the efficiency of manufacturing and assembling the wire harness can be improved.

According to the aspect (2), the protector is in close contact with the trunk lines when protecting the trunk lines of the wire harness, while the protector is integrated with the connector connected to the circuit network, so that the movement of the connector of the selection circuit line fitted to the connector is restricted. As a result, the plurality of circuit lines can be stably arranged by this restriction.

According to the aspect (3), the protector includes the lid and the protector main body, and the protector main body accommodates the circuit network, so that the circuit network can be protected and accommodated, and the maintenance management such as the change of the circuit network can be facilitated by removing the lid.

According to the aspect (4), the connector is integrally formed to be adjacent to the outer side surface of the protector main body, and the terminal whose one end is connected to the circuit network passes through the outer side surface of the protector main body at the other end thereof and extends inside the connector, so that the wiring of the plurality of selection circuit lines can be performed in a space-saving manner, and the plurality of circuit lines can be arranged more stably.

According to the aspect (5), the connector includes the earth terminal fastened to the bolt provided on the vehicle body, so that the circuit network can be grounded via the connector and the terminal while installing the protector. Thereby, the efficiency of the attachment work of the wire harness can be improved.

According to one or more embodiment, connection or disconnection between the selection circuit lines and switching of connection such as branching of the selection circuit lines can be easily realized by changing the circuit network of the protector. Accordingly, even in a case where various connection states of the selection circuit lines are required in the optional sub-harness, the configuration of the optional sub-harness can be simplified and standardized. Therefore, the number of types that needs to be prepared in advance for the optional sub-harnesses can be reduced, and assembling of the wire harness can be simplified. As a result, the efficiency of manufacturing and assembling the wire harness can be improved.

The present invention has been briefly described as above. Further, details of the present invention are further clarified by reading a mode for carrying out the present invention described below with reference to the accompanying drawings.

### BRIEF DESCRIPTION OF THE DRAWINGS

FIG. 1 is an exploded perspective view illustrating main parts of a wire harness according to an embodiment.

FIG. 2 is a top view illustrating a protector shown in FIG. 1.

FIG. 3 is view taken in a direction of an arrow A shown in FIG. 2.

FIG. 4 is a perspective view illustrating a state in which trunk lines of the wire harness is installed in the protector shown in FIG. 1.

### DETAILED DESCRIPTION

Exemplary embodiments of a wire harness of will be described below with reference to the drawings.

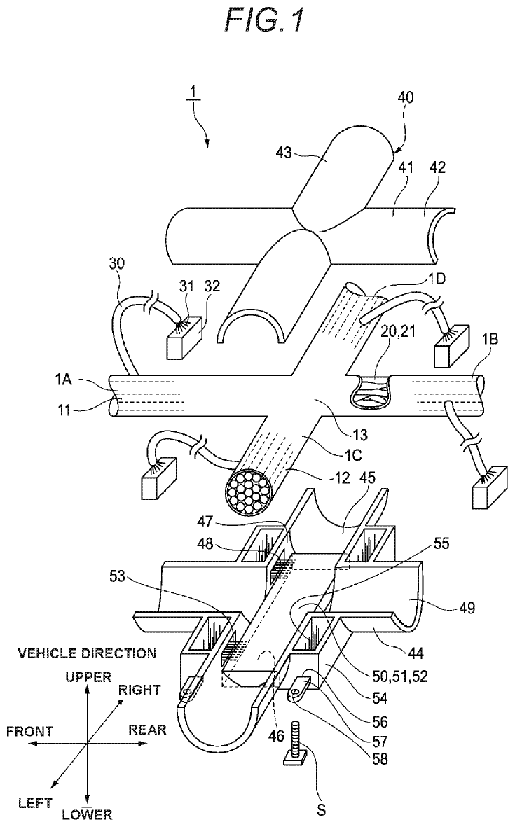

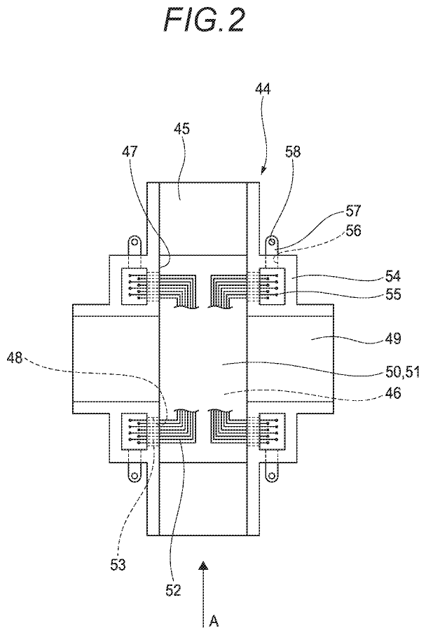

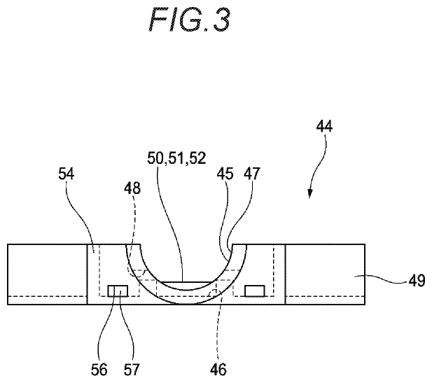

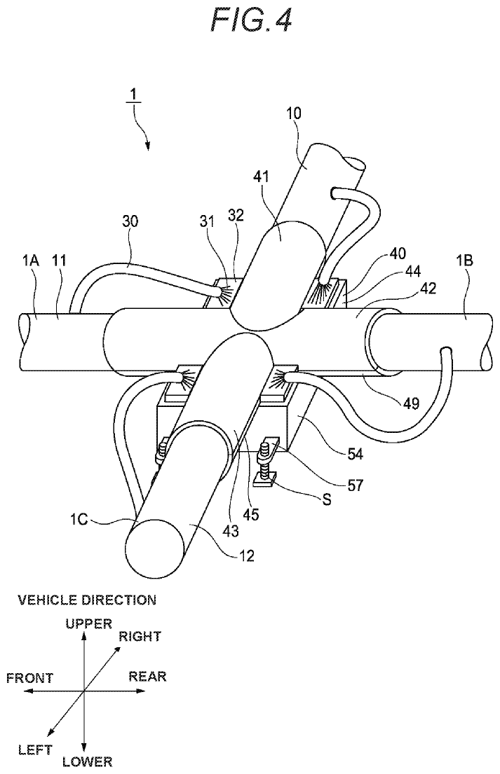

A wire harness 1 according to an embodiment of the present invention will be described with reference to FIGS. 1 to 4. FIG. 1 is an exploded perspective view illustrating main parts of the wire harness 1 according to the present embodiment. FIG. 2 is a top view illustrating a protector 40 shown in FIG. 1. FIG. 3 is view taken in a direction of an arrow A shown in FIG. 2. FIG. 4 is a perspective view illustrating a state in which trunk lines 11, 12 of the wire harness 1 is installed in the protector 40 shown in FIG. 1.

(Overall Configuration of Wire Harness)

First, an overall configuration of the wire harness 1 of the present embodiment will be described.

As illustrated in FIG. 1, the wire harness 1 of the present embodiment is mounted on a vehicle such as an automobile. The wire harness 1 includes first and second trunk lines 11, 12 arranged on a vehicle body B, and a protector 40 having a lid 41 (to be described later) and sandwiching the first and second trunks 11, 12 from an upper-lower direction of the vehicle for protection. A stud bolt (bolt) S is erected on the vehicle body B, and the stud bolt S functions as an electrical ground connection for the vehicle.

The first trunk line 11 of the wire harness 1 is arranged to extend in a front-rear direction of the vehicle on the vehicle body B. The second trunk line 12 of the wire harness 1 is arranged to extend in a left-right (width) direction of the vehicle so as to intersect the first trunk line 11 at a substantially right angle. That is, the wire harness 1 of the present embodiment is routed in a substantially cross shape as a whole, and includes an intersection portion 13 at which the first and second trunk lines 11, 12 intersect with each other.

At the intersection portion 13 of the wire harness 1, the first and second trunk lines 11, 12 are provided so as not to be bulky by being braided in units of circuit lines 21, 31 described below. The intersection portion 13 of the wire harness 1 and a periphery thereof are directly protected by the protector 40.

A portion of the first trunk line 11 located at a vehicle front side with respect to the intersection portion 13 of the wire harness 1 is referred to as a front side portion 1A of the wire harness 1. Similarly, a portion of the first trunk line 11 located at a vehicle rear side is referred to as a rear side portion 1B of the wire harness 1; a portion of the second trunk line 12 located at a vehicle left side is referred to as a left side portion 1C of the wire harness 1, and a portion of the second trunk line 12 located at a vehicle right side is referred to as a right side portion 1D of the wire harness 1.

The wire harness 1 includes a standard sub-harness 20 configured by a plurality of standard circuit lines 21, and an optional sub-harness 30 configured by a plurality of selection circuit lines 31. The standard sub-harness 20 and the optional sub-harness 30 are integrally bundled in each of the first and second trunk lines 11, 12 of the wire harness 1, and the first and second trunk lines 11, 12 are configured as an assembly including the sub-harnesses 20, 30.

At the front side portion 1A and rear side portion 1B of the wire harness 1, the optional sub-harness 30 branch one by one from the first trunk line 11. Similarly, at the left side portion 1C and right side portion 1D of the wire harness 1, the optional sub-harness 30 branch one by one from the second trunk line 12. Harness-side connectors 32 to be fitted to protector-side connectors (connector) 54 of the protector 40 to be described later are provided at a tip end portion of the optional sub-harness 30.

The harness-side connector 32 is a male connector, and is formed in a flat box shape by an electrically insulating synthetic resin or the like. The selection circuit lines 31 of the optional sub-harness 30 are connected to a side surface on one end of the harness-side connector 32. In addition, a plurality of conductive connection-receiving portions (not illustrated) are provided on a side surface of the other end which is to be fitted to a protector-side connector 54 of the protector 40, and the connection-receiving portions are electrically connected to the selection circuit lines 31 of the optional sub-harness 30 respectively.

The protector 40 includes the lid 41 and a protector main body 44 whose one surface opened to the upper side of the vehicle is covered by the lid 41. The lid 41 and the protector main body 44 of the protector 40 are made of an electrically insulating synthetic resin or the like. As described later, the protector body 44 accommodates the circuit network 52 at a bottom therein, and the trunk lines 11, 12 of the wire harness 1 are placed in a state of being stacked on the accommodated circuit network 52. The lid 41 covers the protector main body 44 after the wire harness 1 is placed, so that the protector 40 accommodates and protects the circuit network 52 and the wire harness 1 therein. The lid 41 of the protector 40 is detachably provided to the protector main body 44. Maintenance or replacement can be appropriately performed on the circuit network 52 in the protector main body 44 by removing the lid 41.

Next, the configuration of components will be further described.

(Configuration of Standard Sub-Harness and Optional Sub-Harness)

Next, the configurations of the standard sub-harness 20 and the optional sub-harness 30 will be further described.

As shown in FIG. 1, the standard sub-harness 20 includes a plurality of standard circuit lines 21. The optional sub-harness 30 includes a plurality of selection circuit lines 31. At least one of the plurality of standard circuit lines 21 and selection circuit lines 31 is a circuit line for supplying power, at least another one is a ground line for grounding, and at least more anther one is a signal line or a communication line for transmitting signals.

Each of the standard circuit lines 21 and selection circuit lines 31 is covered with an electrically insulating synthetic resin or the like around a conductor such as a stranded wire. In the standard circuit line 21, a thickness of the conductor, a thickness of the covering, and a material thereof are determined according to a current value and a voltage value which are changed depending on specification of the vehicle type and grade of the vehicle. A length or the like of the selection circuit line 31 is determined according to the specification of the optional sub-harness 30.

Many of the standard circuit lines 21 relate to basic functions of a vehicle, for example, a drive system such as an engine or a motor, and are circuit lines which are mounted standardly on all vehicles. Meanwhile, many of the selection circuit lines 31 relate to additional (optional) functions of a vehicle, such as an acoustic system and a power window system, and are circuit lines to be selectively mounted according to the demand of a vehicle customer (driver).

(Configuration of Protector)

Next, the configuration of protector 40 will be further described.

As shown in FIGS. 1 to 3, the protector 40 includes the lid 41 and the protector main body 44. The protector main body 44 accommodates the circuit network 52 therein, and the intersection portion 13 of the wire harness 1 and the periphery thereof are stacked and placed on the circuit network 52.

The lid 41 is formed in a substantially cross shape corresponding to the intersection portion 13 of the wire harness 1 and the periphery thereof, and includes a first trunk line pressing portion 42 extending in the front-rear direction of the vehicle, and a second trunk line pressing portion 43 extending in the left-right direction of the vehicle so as to intersect the extending direction of the first trunk line pressing portion 42 at a substantially right angle. The cross sections of the first and second trunk line pressing portions 42, 43 are formed in a substantially arc shape. Therefore, when the trunk lines 11, 12 of the wire harness 1 are placed in the protector main body 44, the lid 41 presses an upper half of an outer peripheral surface of the intersection portion 13 of the wire harness 1 and the periphery thereof from above with the first and second trunk line pressing portions 42, 43. The lid 41 protects the trunk lines 11, 12 of the wire harness 1 from coming off the protector 40.

Similarly, the protector main body 44 is formed in a substantially cross shape corresponding to the intersection portion 13 of the wire harness 1 and the periphery thereof. The protector main body 44 includes an accommodation main body 45 extending in the left-right direction of the vehicle, two accommodation branch portions 49 respectively extending in the front-rear direction of the vehicle from both outer side surfaces of an intermediate portion in the extending direction of the accommodation main body 45, and four protector-side connectors (connectors) 54 integrally provided adjacent to both the accommodation main body 45 and the accommodation branch portions 49.

The accommodation branch portions 49 are generally formed in a substantially semi-cylindrical shape divided into two along an axial direction. Each accommodation branch portion 49 is formed in a substantially arc shape in cross section, and is formed to open on the upper side of the vehicle. Therefore, each accommodation branch portion 49 engages with and supports a lower half of the outer peripheral surface of the first trunk line 11 of the wire harness 1, more specifically, the front side portion 1A or the rear side portion 1B of the wire harness 1 in the inner peripheral surface thereof.

Similarly, the accommodation main body 45 is generally formed in a substantially semi-cylindrical shape divided into two along the axial direction, and is formed to open on the upper side of the vehicle. The cross section of the accommodation main body 45 is formed in a substantially U shape at the intermediate portion of the accommodation main body 45 in the extending direction, more specifically, at a portion where the accommodation branch portion 49 has a margin (distance) in both directions of the extending direction of the accommodation main body 45 and crosses in the extending direction. On the other hand, the cross section of the accommodation main body 45 is formed in a substantially arc shape at each end portion of the accommodation main body 45 in the extending direction. Therefore, steps are respectively provided between the intermediate portion and the end portions of the accommodation main body 45.

The accommodation main body 45 has a bottom wall portion 46 formed in a rectangular flat plate shape in the intermediate portion, and two side wall portions 47 erected from both end portions of the bottom wall portion 46. A circuit substrate 50 of the circuit network 52 described later is placed and accommodated on the bottom wall portion 46 of the accommodation main body 45. In one side wall portion 47, two rectangular insertion holes 48 are formed side by side so as to sandwich the accommodation branch portion 49 in the extending direction of the accommodation main body 45. Similarly, in the other side wall portion 47, two rectangular insertion holes 48 are formed side by side so as to sandwich the accommodation branch portion 49 in the extending direction of the accommodation main body 45.

In a state where the circuit substrate 50 of the circuit network 52 is placed on the bottom wall portion 46 of the accommodation main body 45, the trunk lines 11, 12 (intersection portion 13 and the periphery thereof) of the wire harness 1 is stacked and arranged on the circuit substrate 50. At this time, both end portions of the accommodation main body 45 engage with and support a lower half of the outer peripheral surface of the second trunk line 12 of the wire harness 1, more specifically, the left side portion 1C or the right side portion 1D of the wire harness 1 in the inner peripheral surface thereof. The intersection portion 13 of the wire harness 1 is supported by the bottom wall portion 46 of the accommodation main body 45 via the circuit substrate 50.

The four protector-side connectors 54 are arranged on both sides of the extending directions of the accommodation main body 45 and the accommodation branch portions 49 so as to sandwich the accommodation main body 45 and the accommodation branch portions 49. That is, the protector-side connector 54 is integrally formed adjacent to the outer side surface of the protector main body 44 at each of the four corners of connection parts of the accommodation main body 45 and the accommodation branch portions 49.

The protector-side connector 54 is formed in a substantially box shape by electrically insulating synthetic resin or the like, a side surface on the other end of the protector-side connector 54 is formed to be open to the upper side of the vehicle, and a plurality of conductive connection portions 55 are provided to expose toward the upper side of the vehicle. The harness-side connector 32 of the optional sub-harness 30 is fitted to the protector-side connector 54 of the protector 40, so that the connection portion 55 of the protector-side connector 54 is electrically connected with the connection-receiving portion of the harness-side connector 32.

Further, insertion holes 56 are respectively formed on a side surface of the protector-side connector 54 which is on an outer side in the extending direction of the accommodation main body 45. An earth terminal 57 having a thin plate shape is inserted into each insertion hole 56. The earth terminal 57 is connected to a ground connection portion (not shown) of the protector-side connector 54 at one end portion thereof. A bolt insertion hole 58 is formed at the other end portion of the earth terminal 57, and a stud bolt S is inserted into and fastened to the bolt insertion hole 58. The earth terminal 57 is grounded by this fastening.

The circuit network 52 configures a part of circuit lines for implementing selectively additional specification in the wire harness 1 and is provided on a thin plate-shaped circuit substrate 50. Specifically, the circuit substrate 50 includes an electrically insulating substrate main body 51, and the circuit network 52 is formed on the substrate main body 51 as a printed circuit substrate. In a case of forming a relatively complex circuit network 52, the circuit network 52 is formed on the substrate main body 51 of the circuit substrate 50 using a multilayer printed circuit substrate.

The circuit network 52 is formed as a wiring pattern, of conductive foil such as copper foil, attached to a front surface, a back surface, or an interface of layers in a thickness direction of the substrate main body 51 of the circuit substrate 50. That is, the circuit network 52 includes a plurality of wires in the wiring pattern. Further, a plurality of terminals 53 arranged on the circuit substrate 50 is electrically connected to the wires of the circuit network 52 at one end.

Parts of the plurality of terminals 53 pass through the four insertion holes 48 of the side wall portions 47 of the accommodation main body 45 of the protector 40 and pass through the outer side surfaces of the protector main body 44. The penetrating terminal 53 is extended inside the protector-side connector 54 and is electrically connected to one end of the connection portion 55 of the protector-side connector 54. By this connection, the protector-side connector 54 is electrically connected to the circuit network 52 through the connection portions 55 and the terminals 53. That is, by fitting the harness-side connector 32 to the protector-side connector 54, the selection circuit line 31 of the optional sub-harness 30 is connected to the circuit network 52 through the harness-side connector 32 and the protector-side connector 54.

The four protector-side connectors 54 are also connected to each other via the wires of the circuit network 52 in portion or all. Although the plurality of wires is electrically separated from one another, a part of the wires are electrically connected to one another. In a case where the plurality of wires is separated at intersecting positions in a plane, the wires are arranged on different planes or layers so as to be electrically separated. In a case where the wires disposed on different planes or layers are connected to each other, the substrate main body 51 of the circuit substrate 50 is electrically connected using a through hole penetrating in the thickness direction. Thus, connection or disconnection of the selection circuit lines 31 of the optional sub-harness 30 and switching of connection such as branching of the selection circuit lines 31 can be easily implemented by appropriately changing the circuit network 52.

(Installation of Wire Harness)

Next, the installation of the wire harness 1 will be described.

As shown in FIG. 1, in the wire harness 1 configured as above, the circuit substrate 50 of the circuit network 52 is placed on the accommodation main body 45 of the protector main body 44. The first and second trunk lines 11, 12 of the wire harness 1 are arranged in the protector main body 44. As shown in FIG. 4, after this arrangement, the harness-side connectors 32 are respectively fitted to the protector-side connectors 54. According to such fitting, the selection circuit lines 31 of the optional sub-harness 30 branched from the trunk lines 11, 12 of the wire harness 1 are connected to the circuit network 52.

Further, the protector main body 44 is installed on the vehicle body B in the state of such placing. At the same time as this installation, the earth terminal 57 of the protector-side connector 54 is inserted into the stud bolt S and fastened. According to such fastening, the protector-side connector 54 is grounded as it is. As a result of such grounding, the selection circuit lines 31 of the optional sub-harness 30 and the circuit network 52 are grounded.

(Advantages of Wire Harness of Present Embodiment)

As described above, according to the wire harness 1 of the present embodiment, the protector 40 includes the circuit network 52 configuring a part of circuit lines for implementing selectively additional specification in the wire harness 1. The selection circuit lines 31 of the optional sub-harness 30 branched from the trunk lines 11, 12 of the wire harness 1 are connected to the circuit network 52 of the protector 40. Thus, connection or disconnection between the selection circuit lines 31 and switching of connection such as branching of the selection circuit lines 31 can be easily realized by changing the circuit network 2 of the protector 40. Accordingly, even in a case where various connection states of the selection circuit lines 31 are required in the optional sub-harness 30, the configuration of the optional sub-harness 30 can be simplified and standardized. Therefore, the number of types that needs to be prepared in advance for the optional sub-harnesses 30 can be reduced, and assembling of the wire harness 1 can be simplified. As a result, the efficiency of manufacturing and assembling the wire harness 1 can be improved.

According to the wire harness 1 of the present embodiment, the protector 40 is integrated with the protector-side connector (connector) 54 connected to the circuit network 52. The selection circuit lines 31 of the optional sub-harness 30 branched from the trunk lines 11, 12 of the wire harness 1 are connected to the circuit network 52 via the protector-side connector 54. Therefore, the protector 40 is in close contact with the trunk lines 11, 12 when protecting the trunk lines 11, 12 of the wire harness 1, while the protector 40 is integrated with the protector-side connector 54 connected to the circuit network 52, so that the movement of the harness-side connector 32 of the selection circuit line 31 fitted to the protector-side connector 54 is restricted. As a result, the plurality of circuit lines 31 can be stably arranged by this restriction.

According to the wire harness 1 of the present embodiment, the protector 40 includes the lid 41 and the protector main body 44 whose one open surface is covered by the lid 41. The protector main body 44 accommodates the circuit network 52, and the protector-side connector (connector) 54 integrally formed on the protector main body 44 is connected to the circuit network 52. Therefore, the circuit network 52 can be protected and accommodated, and the maintenance management such as the change of the circuit network 52 can be facilitated by removing the lid 41.

According to the wire harness 1 of the present embodiment, the protector main body 44 is integrally formed with the protector-side connector (connector) 54 which is adjacent to the outer side surface of the protector main body 44. In the protector-side connector 54, the terminal 53 whose one end is connected to the circuit network 52 passes through the outer side surface of the protector main body 44 and extends inside the protector-side connector 54. Therefore, the wiring of the plurality of selection circuit lines 31 can be performed in a space-saving manner, and the plurality of circuit lines 31 can be arranged more stably.

According to the wire harness 1 of the present embodiment, the protector-side connector (connector) 54 has the earth terminal 57 fastened to the stud bolt (bolt) S provided on the vehicle body B. Therefore, the circuit network 52 can be grounded via the protector-side connector 54 and the terminal 53 while installing the protector 40. Thereby, the efficiency of the attachment work of the wire harness 1 can be improved.

Although the description of the specific embodiments is completed above, aspects of the present invention are not limited to these embodiments, and may be appropriately modified, improved, or the like.

Here, characteristics of the embodiments of the wire harness 1 according to the present invention described above are summarized briefly in the following [1] to [5], respectively.

[1] A wire harness (1) comprising:

a standard sub-harness (20) including a standard circuit line (21);

an optional sub-harness (30) including a selection circuit line (31); and

a protector (40) protecting trunk lines (11, 12) including the standard sub-harness,

wherein the protector (40) includes a circuit network (52) configuring a part of the selection circuit line so as to implement selectively added function in the wire harness (1), and

wherein the selection circuit line (31) of the optional sub-harness (30) branched from the trunk line (11, 12) is connected to the circuit network (52) of the protector (40).

[2] The wire harness (1) according to [1],

wherein the protector (40) is integrated with a connector (protector-side connector 54) connected to the circuit network (52), and the selection circuit line (31) of the optional sub-harness (30) branched from the trunk lines (11, 12) of the wire harness (1) is connected to the circuit network (52) via the connector (protector-side connector 54).

[3] The wire harness (1) according to [2],

wherein the protector (40) includes a protector main body (44) and a lid (41) covering one open surface of the protector main body (44),

wherein the protector main body (44) accommodates the circuit network (52), and

wherein the connector (protector-side connector 54) is connected to the circuit network (52).

[4] The wire harness (1) according to [3],

wherein the protector main body (44) is integrally formed with the connector (protector-side connector 54) which is adjacent to an outer side surface of the protector main body (44), and

wherein the connector (protector-side connector 54) is configured such that a terminal (53) whose one end is connected to the circuit network (52) passes through the outer side surface of the protector main body (44) and extends inside the connector (protector-side connector 54).

[5] The wire harness (1) according to [4],

wherein the connector (protector-side connector 54) includes an earth terminal (57) fastened to a bolt (stud bolt S) provided on a vehicle body (B).

### DESCRIPTION OF REFERENCE NUMERALS AND SIGNS

1 wire harness
1A front side portion
1B rear side portion
1C left side portion
1D right side portion
11 first trunk line
12 second trunk line
13 intersection portion
20 standard sub-harness
21 standard circuit line
30 optional sub-harness
31 selection circuit line
32 harness-side connector
40 protector
41 lid
42 first trunk line pressing portion
43 second trunk line pressing portion
44 protector main body
45 accommodation main body
46 bottom wall portion
47 side wall portion
48 insertion hole
49 accommodation branch portion
50 circuit substrate
51 substrate main body
52 circuit network
53 terminal
54 protector-side connector (connector)
55 connection portion
56 insertion hole
57 earth terminal
58 bolt insertion hole
B vehicle body
S stud bolt

What is claimed is:

1. A wire harness comprising:
a standard sub-harness including a standard circuit line;
an optional sub-harness including a selection circuit line; and
a protector protecting trunk lines including the standard sub-harness,
wherein the protector includes a circuit network configuring a part of the selection circuit line so as to implement selectively added function in the wire harness, and
wherein the selection circuit line of the optional sub-harness branched from the trunk line is connected to the circuit network of the protector.

2. The wire harness according to claim 1,
wherein the protector is integrated with a connector connected to the circuit network, and the selection circuit line of the optional sub-harness branched from the trunk lines of the wire harness is connected to the circuit network via the connector.

3. The wire harness according to claim 2,
wherein the protector includes a protector main body and a lid covering one open surface of the protector main body,
wherein the protector main body accommodates the circuit network, and
wherein the connector is connected to the circuit network.

4. The wire harness according to claim 3,
wherein the protector main body is integrally formed with the connector which is adjacent to an outer side surface of the protector main body, and
wherein the connector is configured such that a terminal whose one end is connected to the circuit network passes through the outer side surface of the protector main body and extends inside the connector.

5. The wire harness according to claim 4,
wherein the connector includes an earth terminal fastened to a bolt provided on a vehicle body.
